(19) United States
(12) Patent Application Publication
(10) Pub. No.: US 2019/0006628 A1
(43) Pub. Date: Jan. 3, 2019

(54) Organic Light-Emitting Diode Device and Manufacturing Method Thereof and Display Panel

(71) Applicants: BOE Technology Group Co., Ltd., Beijing (CN); Hefei Xinsheng Optoelectronics Technology Co., Ltd, Hefei City (CN)

(72) Inventors: Lei Huang, Beijing (CN); Kai Xu, Beijing (CN); Zhijie Ye, Beijing (CN); Xinxin Wang, Beijing (CN); Rui Peng, Beijing (CN); Wenbin Jia, Beijing (CN)

(73) Assignees: BOE Technology Group Co., Ltd., Beijing (CN); Hefei Xinsheng Optoelectronics Technology Co., Ltd ., Hefei City (CN)

(21) Appl. No.: 15/736,330

(22) PCT Filed: Jun. 5, 2017
(86) PCT No.: PCT/CN2017/087182

§ 371 Date: Dec. 14, 2017

(30) Foreign Application Priority Data
Oct. 17, 2016 (CN) 201610903223.8

(51) Int. Cl. H01L 51/52; H01L 27/32; H01L 51/56

(52) U.S. Cl. CPC H01L 51/5275; H01L 51/5212; H01L 51/56; H01L 27/32; H01L 51/5234

(57) ABSTRACT

An organic light-emitting diode device, a manufacturing method thereof, and a display panel are provided. The organic light-emitting diode device includes: a first electrode layer; a second electrode layer; a third electrode layer; an electrically induced refractive index change layer and an organic light-emitting layer. The electrically induced refractive index change layer is disposes between the first electrode layer and the second electrode layer and is configured to allow its own refractive index to be changed in operation according to a voltage difference between the first electrode layer and the second electrode layer. The organic light-emitting layer is disposed between the second electrode layer and the third electrode layer and is configured to emit light in operation according to a voltage difference between the second electrode layer and the third electrode layer.

### TECHNICAL FIELD

Embodiments of the present disclosure relate to an organic light-emitting diode device and a manufacturing method thereof and to a display panel.

### BACKGROUND

Organic light-emitting diodes are favored by people because they have advantages such as self-illumination, low power consumption, rapid response speed, flexibility, high contrast, wide viewing angle, super light and thin profile, low cost and the like.

According to the direction of output light, organic light-emitting diode devices can be categorized as bottom emission organic light-emitting diode devices, top emission organic light-emitting diode devices and double-side emission organic light-emitting diode devices. A bottom emission organic light-emitting diode device is an organic light-emitting diode device of which light is emitted from the side where the base substrate is located, a bottom emission organic light-emitting diode device is an organic light-emitting diode device of which light is emitted from a top side of the device, and a double-side emission organic light-emitting diode device is an organic light-emitting diode device of which light is emitted from the side where the base substrate is located and a top side of the device concurrently. However, emission wavelengths of existing organic light-emitting diode devices cannot be tuned after completing the design of the devices, so the color deviation problem due to aging of devices cannot be solved.

### SUMMARY

An embodiment of the present disclosure provides an organic light-emitting diode device and the organic light-emitting diode device comprises: a first electrode layer; a second electrode layer, which is at least partially overlapped with the first electrode layer; a third electrode layer, which is disposed at a side of the second electrode layer away from the first electrode layer and is at least partially overlapped with the second electrode layer; an electrically induced refractive index change layer and an organic light-emitting layer. The electrically induced refractive index change layer is disposes between the first electrode layer and the second electrode layer and is configured to allow a refractive index of the electrically induced refractive index change layer to be changed in operation according to a voltage difference between the first electrode layer and the second electrode layer. The organic light-emitting layer is disposed between the second electrode layer and the third electrode layer and is configured to emit light in operation according to a voltage difference between the second electrode layer and the third electrode layer.

An embodiment of the present disclosure further provides a display panel, and the display panel comprises the above-mentioned organic light-emitting diode device.

An embodiments of the present disclosure further provides a manufacturing method of an organic light-emitting diode device and the manufacturing method comprises: forming the first electrode layer; forming the second electrode layer; forming the third electrode layer at a side of the second electrode layer away from the first electrode layer; forming the electrically induced refractive index change layer between the first electrode layer and the second electrode layer; and forming the organic light-emitting layer between the second electrode layer and the third electrode layer.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematically structural diagram of an organic light-emitting diode device provided by an embodiment of the present disclosure;

FIG. 2 is a schematically structural diagram of an organic light-emitting diode device provided by another embodiment of the present disclosure;

FIG. 3 is a schematically structural diagram of a display panel provided by still another embodiment of the present disclosure;

FIG. 4 is a schematic diagram of a display device provided by still another embodiment of the present disclosure; and

FIG. 5 is a flowchart of a manufacturing method of an organic light-emitting diode device provided by further still another embodiment of the present disclosure

### DETAILED DESCRIPTION

The technical solutions of the embodiments will be described in a clearly and fully understandable way in connection with the drawings related to the embodiments of the present disclosure, and embodiments of the present disclosure and more features and favorable details of them are illustrated more comprehensively referring to the limitative exemplary embodiments described in the drawings and the below descriptions. It should be noted that features shown in drawings are not drawn in a real scale necessarily. The known materials, components, and process technology are omitted in the present disclosure in order not to make the exemplary embodiments of the present disclosure obscure. The given examples aim to help better understand implementation of the embodiments of the present disclosure and to further enable the person skilled in the art to implement the exemplary embodiments. Therefore, these examples are not supposed to be interpreted as limitative of the embodiments of the present disclosure.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Besides, in each embodiments of the present disclosure, same or similar reference numbers indicate same or similar components.

Embodiments of the present disclosure provide an organic light-emitting diode device and a manufacturing method thereof, a display panel and a display device. By introducing an electrically induced refractive index change layer, an emission wavelength of the organic light-emitting diode device can be tuned and color deviation due to aging of the device can be reduced or eliminated.

At least one embodiment of the present disclosure provides an organic light-emitting diode device and the organic light-emitting diode device comprises: a first electrode layer; a second electrode layer, which is at least partially overlapped with the first electrode layer; a third electrode layer, which is at least partially overlapped with the second electrode layer; an electrically induced refractive index change layer; and an organic light-emitting layer. The organic light-emitting layer is disposed between the second electrode layer and the third electrode layer and is configured to emit light in operation according to a voltage difference between the second electrode layer and the third electrode layer. The electrically induced refractive index change layer is disposes between the first electrode layer and the second electrode layer and is configured to allow a refractive index of the electrically induced refractive index change layer to be changed in operation according to a voltage difference between the first electrode layer and the second electrode layer.

At least one embodiment of the present disclosure is able, by introducing an electrically induced refractive index change layer in the organic light-emitting diode device and controlling a voltage difference between a first electrode layer and a second electrode layer, to control an optical cavity length of the organic light-emitting diode device and an optical path of light rays in the organic light-emitting diode device and further to control and tune the emission wavelength of the organic light-emitting diode device.

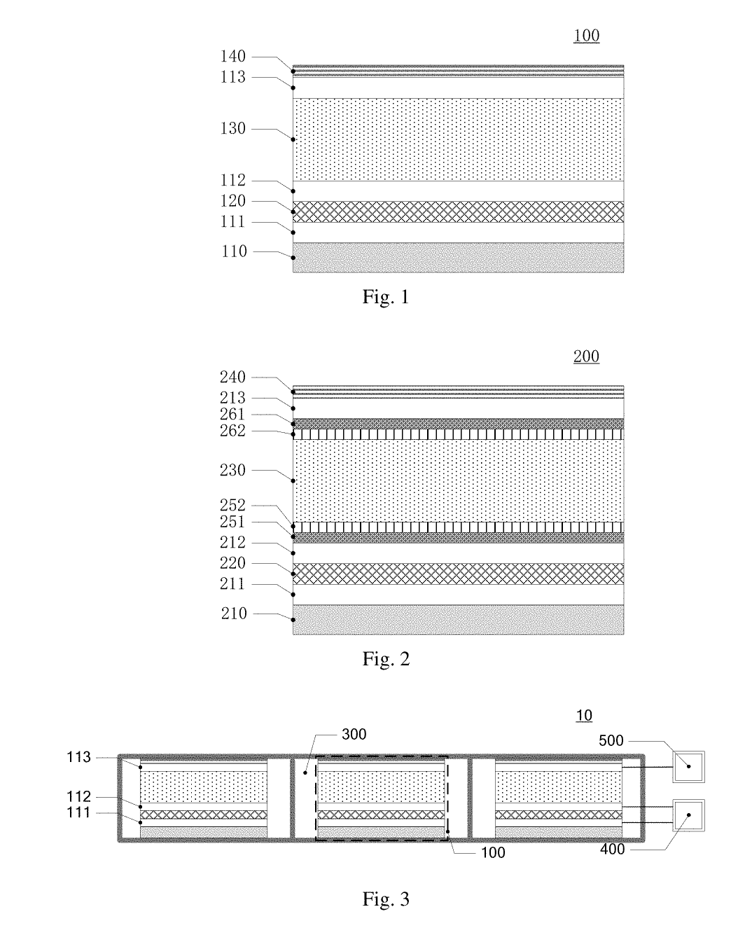

For example, an embodiment of the present disclosure provides an organic light-emitting diode device 100. As illustrated in FIG. 1, the organic light-emitting diode device 100 comprises a first electrode layer 111, an electrically induced refractive index change layer 120, a second electrode layer 112, an organic light-emitting layer 130 and a third electrode layer 113, which layers are disposed sequentially. That is, the third electrode layer 113 is disposed at a side of the second electrode layer away from the first electrode layer. The electrically induced refractive index change layer 120 is configured to enable a refractive index of the electrically induced refractive index change layer 120 itself to be changed in operation according to a voltage difference between the first electrode layer 111 and the second electrode layer 112; the organic light-emitting layer 130 is configured to emit light in operation according to a voltage difference between the second electrode layer 112 and the third electrode layer 113.

For example, in order to provide protection, support and the like, the organic light-emitting diode device 100 may further comprise a substrate 110. The substrate 110 can be a glass substrate, a quartz substrate, a plastic substrate (e.g., a polyethylene terephthalate (PET) substrate), or other substrate made of a proper material.

In the embodiment illustrated in FIG. 1, the first electrode layer 111, the electrically induced refractive index change layer 120, the second electrode layer 112, the organic light-emitting layer 130 and the third electrode layer 113 are disposed on the substrate sequentially. The electrically induced refractive index change layer in this structure is closer to the substrate compared with the organic light-emitting layer. However, embodiments of the present disclosure are not limit to this situation. For example, in another embodiment, the electrically induced refractive index change layer is disposed farther away from the substrate compared with the organic light-emitting layer; that is, the third electrode layer, the organic light-emitting layer, the second electrode layer, the electrically induced refractive index change layer and the first electrode layer are disposed on the substrate sequentially.

For example, when the organic light-emitting layer 130 is acted under a voltage applied across two its sides, electrons and holes are injected into the organic light-emitting layer and recombine to form exitons which can radiate light, and the wavelength of the emitted light is determined by the material(s) of the organic light-emitting layer 130. For example, the luminescence intensity of the organic light-emitting layer 130 is related with the amplitude of the current running through it. The material for forming the organic light-emitting layer 130 comprises an organic fluorescence luminescent material or an organic phosphorescent luminescent material. For example, as for the organic fluorescence luminescent materials, light-emitting materials comprising at least one of DCM, DCJTB, DCJ, DCJT and the like can emit red light; light-emitting materials comprising at least one of C-545T (coumarin), C-545MT, qinacridone (QA), polyaromatic hydrocarbons (PAHs) and the like can emit green light; light-emitting materials comprising at least one of TBP, DSA-Ph, BD1, BD2 and the like can emit blue light; organic fluorescence luminescent materials comprising both DCJTB and TBP can emit white light. As for the organic phosphorescent luminescent materials, light-emitting materials comprising at least one of PtOEP, Btp₂Ir(acac), Ir(piq)₂(acac) and the like can emit red light; light-emitting materials comprising at least one of Ir(ppy)_{3,} Ir(mppy)_{3,} (ppy)₂Ir(acac) and the like can emit green light; light-emitting materials comprising at least one of FIrpic, FIrtaz, FIrN₄ and the like can emit blue light.

For example, transparent materials of which the refractive index can be changed under an applied external electric field can be chosen for the materials of the electrically induced refractive index change layer 120. The refractive index of the electrically induced refractive index change layer 120 changes under the externally applied electric field, and accordingly changes the optical path of the light passing through the electrically induced refractive index change layer 120, so that the optical path of the light passing through the electrically induced refractive index change layer 120 can be tuned, the wavelength of the light passing through the electrically induced refractive index change layer 120 can be further tuned, and color deviation due to aging of the device can be reduced or eliminated. Compared to tuning of the optical path by changing a physical length, tuning of the optical path by changing the refractive index can avoid mechanical movements for tuning the optical path and the limitation on the tuning frequency caused by the mechanical movements, thus the stability and the tuning frequency of the related devices during tuning the optical path can be increased.

For example, the material for forming the electrically induced refractive index change layer 120 can be at least one of an electro-optical ceramic material, an organic electro-optical material, and an electro-optical crystalline material. The electro-optical ceramic material can be chosen from lead magnesium niobate (PMN)—lead titanate (PT) or other suitable material. The organic electro-optical material can be chosen from potassium dideuterium phosphate (DKDP), ammonium dihydrogen phosphate (ADP) or other suitable material. The electro-optical crystalline material can be chosen from lithium niobate crystals (LN) and lithium tantalate (LT) crystals. The electrically induced refractive index change layer 120 can be chosen according to the requirement on the electro-optical coefficient of the organic light-emitting diode device 100 relative to the electrically induced refractive index change layer 120 (i.e., a ratio between the applied electric field and the refractive index change of the electrically induced refractive index change layer), the requirement on transmittance, the requirement on response speed (e.g., tuning efficiency) and other factors. During a specific process of forming the electrically induced refractive index change layer 120, an appropriate manufacturing process can be chosen according to the material of the electrically induced refractive index change layer 120, for example, evaporation, coating and chemical vapor deposition can be chosen.

For example, the second electrode layer 112 is the anode electrode layer of the organic light-emitting diode device 100, and light emitted from the organic light-emitting layer 130 needs to pass through the second electrode layer 112, so the material for forming the anode of the second electrode layer 112 needs good electrical conductivity and high transmittance for the light emitted from the organic light-emitting layer 130, that is, the second electrode layer 112 needs to be a transparent conductive layer. In order to enhance the injection of holes into the organic light-emitting layer 130 and improve the properties of the organic light-emitting diode device 100, the material for forming the second electrode layer 112 can be a material having a high work function. For example, the material of the second electrode layer 112 can be indium tin oxide (ITO), indium zinc oxide (IZO), zinc oxide (ZnO), aluminum zinc oxide (AZO) or other suitable material. The second electrode layer 112 can be made through sputtering, chemical vapor deposition, laser pulse dissolution, ion-beam assisted deposition or other proper process. The specific manufacturing method can be chosen according to factors such as the material of the second electrode layer 112, the material of the transparent substrate, process compatibility, and the like.

For example, light emitted from the organic light-emitting layer can exit from the third electrode layer and, in this case, the organic light-emitting diode device is called as a top emission organic light-emitting diode device. Light emitted from the organic light-emitting layer can exist from the first electrode layer and, in this case, the organic light-emitting diode device is called as a bottom emission organic light-emitting diode device. Light emitted from the organic light-emitting layer can exist from both the first electrode layer and the third electrode layer and, in this case, the organic light-emitting diode device is called as a double-side emission organic light-emitting diode device.

For example, as for the top emission organic light-emitting diode device 100, light emitted from the organic light-emitting layer 130 exists from the third electrode layer 113, and the third electrode layer 113 is the cathode electrode layer of the organic light-emitting diode device 100, so the material for forming the third electrode layer 113 need good conductivity and high transmittance of the light emitted from the organic light-emitting layer 130, that is, the third electrode layer 113 needs to be a transparent conductive layer. For example, the third electrode layer 113 can be made of a transparent alloy material (e.g., Mg:Ag or Ca:Ag), a transparent conductive oxide material (e.g., ITO or AZO), a combination of a transparent alloy material and a transparent conductive oxide material (e.g., Mg:Ag/ITO), or other proper material. Because light exits from the third electrode layer 113, in order to enhance the efficiency of the organic light-emitting diode device 100, the material for forming the first electrode layer 111 can be chosen from materials having high reflectivity for the light emitted from the organic light-emitting layer 130 (e.g., Al, Ag, Au, Ni or Pt), or, a separate reflective layer is formed additionally.

For example, in order to decrease the total reflection of the light emitted from the organic light-emitting layer 130 while existing (at the interface formed by the light exiting surface and the outside environment medium such as atmosphere) and increase output of the light; as for a top emission organic light-emitting diode device 100, a cover layer 140 can be included, and this cover layer 140 is disposed on the side of the third electrode layer 113, which side is away from the second electrode layer 112. The cover layer 140 can be an inorganic cover layer or an organic cover layer. For example, the inorganic cover layer can be formed by a glass substrate the upper surface (the side in contact with the outside environment such as atmosphere) of which is rough, a micro lens layer, or a scattering layer. The organic cover layer can be formed by a small organic molecule Alq film. For example, the cover layer 140 can further functions a protection to the third electrode layer 113.

For example, as for a top emission organic light-emitting diode device 100, the substrate 110 can also be a non-transparent substrate.

For example, as for a bottom emission organic light-emitting diode device 100, the light emitted from the organic light-emitting layer 130 exists from the first electrode layer 111, so the material for forming the first electrode layer 111 needs to possess good electrical conductivity and high transmittance for the light emitted from the organic light-emitting layer 130, that is, the first electrode layer 111 needs to be a transparent conductive layer. For example, the first electrode layer 111 can be made of a transparent conductive glass material, a transparent conductive oxide material, a transparent alloy material or other proper material. The third electrode layer 113 is the cathode electrode layer of the organic light-emitting diode device 100, so the material for forming the third electrode layer 113 needs to possess good electrical conductivity. Because light exits from the first electrode layer 111, in order to enhance the efficiency of the organic light-emitting diode device 100, the material for forming the third electrode layer 113 can be chosen from materials having high reflectivity for the light emitted from the organic light-emitting layer 130 (e.g., metal or metal alloy), or a separate reflective layer is formed. In order to enhance the injection effect of electrons into the organic light-emitting layer 130 and improve the properties of the organic light-emitting diode device 100, the material for forming the third electrode layer 113 can be a material having a low work function. For example, the material of the third electrode layer 113 can be chosen from Ca, Li, MgAg (90% Mg), LiAl (0.6% Li) or other proper material.

For example, as for a double-side emission organic light-emitting diode device 100, the light emitted from the organic light-emitting layer 130 exists from both the first electrode layer 111 and the third electrode layer 113. So the materials for forming the first electrode layer 111 and the third electrode layer 113 both need to possess good electrical conductivity and high transmittance for the light emitted from the organic light-emitting layer 130, that is, both the first electrode layer 111 and the third electrode layer 113 need to be a transparent conductive layer. For example, the first electrode layer 111 can be made of a transparent conductive glass material, a transparent conductive oxide material, a transparent alloy material or other proper material. For example, the third electrode layer 113 can be made of a transparent alloy material (e.g., Mg:Ag or Ca:Ag), a transparent conductive oxide material (e.g., ITO or AZO), a combination of transparent alloy material and a transparent conductive oxide material (e.g., Mg:Ag/ITO), or other proper material.

An operating principle of the organic light-emitting diode device 100 is illustrated below in connection with FIG. 1. For example, as for the organic light-emitting diode device 100, the second electrode layer 112 is the anode electrode layer, the third electrode layer 113 is the cathode electrode layer, the second electrode layer 112 and the third electrode layer 113 can be used to apply a voltage across the organic light-emitting layer 130, and the organic light-emitting layer 130 emits light according to the voltage difference between the second electrode layer 112 and the third electrode layer 113. Because the first electrode layer 111 and the third electrode layer 113 have certain reflectivity towards the light emitted from the organic light-emitting layer 130, a resonant cavity effect exists within the organic light-emitting diode device 100. The resonant cavity effect refers to the effect that photon densities at different energy states are redistributed so that light output from the resonant cavity has a specific wave length λthat conforms to the mode of the resonant cavity. For the light perpendicular to the light exiting surface, the wavelength of the output light needs to satisfy the equation of 2Δ=mλ(m=1, 2, 3, . . . ), where Δ indicates the optical path, which equals to the result of the refractive index of the medium multiplying the distance that the light passes through the medium. So if the optical path of the resonant cavity changes, the wavelength of the light output from the resonant cavity changes accordingly. For the organic light-emitting diode device 100, the electrically induced refractive index change layer 120 is located in the resonant cavity formed by the first electrode layer 111 and the third electrode layer 113. The first electrode layer 111 and the second electrode layer 112 can be used to apply a voltage across the electrically induced refractive index change layer 120, and the electrically induced refractive index change layer 120 can tune its own refractive index according to the voltage difference between the first electrode layer 111 and the second electrode layer 112, and further tune the optical path of the light in the resonant cavity. So, by controlling the voltage difference between the first electrode layer 111 and the second electrode layer 112 to change the length of the optical cavity of the organic light-emitting diode device 100 and the optical path of light in the organic light-emitting diode device 100, the wavelength of the output light from the organic light-emitting diode device 100 can be tuned, the wavelength of light passing through the electrically induced refractive index change layer 120 can be further tuned and the color deviation due to aging of the device can be reduced or eliminated. Compared to tuning an optical path by changing a physical length, tuning the optical path by changing a refractive index can avoid mechanical movements during tuning the optical path and avoid the limitation to the tuning frequency caused by the mechanical movements, so as to increase the stability and the tuning frequency of the organic light-emitting diode device 100 during tuning the optical path thereof. Besides, the resonant cavity effect can also allow a full width at half maximum (FWHM) to become narrower, so as to increase the color gamut and the image quality of the displayed images of the display device prepared based on the organic light-emitting diode device 100.

For example, another embodiment of the present disclosure provides an organic light-emitting diode device 200. As illustrated in FIG. 2, compared to the organic light-emitting diode device 100 illustrated in FIG. 1, the organic light-emitting diode device 200 further comprises one or more of a hole transport layer 252, an electron transport layer 262, a hole injection layer 251 and an electron injection layer 261, in addition to a first electrode layer 211, an electrically induced refractive index change layer 220, a second electrode layer 212, an organic light-emitting layer 230 and a third electrode layer 213. For example, in order to provide protection and support and the like, the organic light-emitting diode device 200 further comprises a transparent substrate 200. For example, in order to decrease the total reflection of the light emitted from the organic light-emitting layer 230 while existing the device (at an interface formed by the light exiting surface and the outside environment medium such as atmosphere) and increase the output of the light; as for a top emission organic light-emitting diode device 200, a cover layer 240 can be included.

By introducing the electrically induced refractive index change layer 220 and controlling the voltage difference between the first electrode layer 211 and the second electrode layer 212, the optical cavity length of the organic light-emitting diode device 200 and the optical path of the light in the organic light-emitting diode device 200 are controlled and the emission wavelength of the organic light-emitting diode device 200 are controlled and tuned as a result.

The first electrode layer 211, the electrically induced refractive index change layer 220, the second electrode layer 212, the organic light-emitting layer 230, the third electrode layer 213, the transparent substrate 210, the cover layer 240 are the same as those of the organic light-emitting diode device 100 illustrated in FIG. 1, and repeat description is omitted here. Descriptions about the hole transport layer 252, the electron transport layer 262, the hole injection layer 251 and the electron injection layer 261 are given below in connection with FIG. 2.

For example, the hole transport layer 252 and/or the hole injection layer 251 are disposed between the second electrode layer 212 and the organic light-emitting layer 230. If both the hole transport layer 252 and the hole injection layer 251 are provided, the hole transport layer 252 is disposed between the hole injection layer 251 and the organic light-emitting layer 230. The electron transport layer 262 and/or the electron injection layer 261 are disposed between the third electrode layer 213 and the organic light-emitting layer 230. If both electron transport layer 262 and the electron injection layer 261 are provided, the electron transport layer 262 is disposed between the electron injection layer 261 and the organic light-emitting layer 230. For example, the material of the hole transport layer 252 can be chosen from materials having high hole mobility, relative small electron affinity, relative low ionization energy and high thermal stability. For example, the hole transport layer 252 can be made of TPD, NPB, m-MTDATA or other proper material. For example, the material of the electron transport layer 262 can be chosen from materials which have strong acceptability to electrons and can transport electrons effectively under a positive bias. For example, the electron transport layer 262 can be made of BND, OXD, TAZ or other proper material. For example, the material of the hole injection layer 251 can be chosen from materials of which the HOMO (highest occupied molecular orbital) energy can best match the work function of the second electrode layer 212. For example, the hole injection layer 251 can be made of CuPc (Copper(II) phthalocyanine), TNATA, PEDOT (PEDT: PSS) or other proper material. For example, the electron injection layer 261 is configured to assist to inject electrons into the organic layer from the cathode, and by adopting an electron-injection material, the electron injection layer 261 can be made of a corrosion-resistant material having a high work function (e.g., Al, Ag). For example, the electron injection layer 261 can be made of lithium oxide, lithium boron oxide, potassium silicon oxide or other proper material. The hole transport layer 252, the electron transport layer 262, the hole injection layer 251 or the electron injection layer 261 can improve the effect of the injection of electrons or holes into the organic light-emitting layer 230, and further improve the performance of the organic light-emitting diode device 200.

For example, another embodiment of the present disclosure provides a display panel. The display panel 10 comprises above-mentioned organic light-emitting diode device 100 or organic light-emitting diode device 200, and the display panel 10 comprising the organic light-emitting diode device 100 is illustrated below for an example. As illustrated in FIG. 3, the display panel 10 comprises a plurality of sub-pixels 300, and the organic light-emitting diode device is disposed within at least part of the sub-pixels 300. The display panel 10 can further comprise a voltage control circuit 400, and the voltage control circuit 400 is configured to apply a first voltage to the first electrode layer 111 and a second voltage to the second electrode layer 112. The display panel 10 can further comprise a display driving circuit 500, and the display driving circuit 500 is configured to apply a third voltage to the third electrode layer 113. Although the voltage control circuit 400 and the display driving circuit 500 are provided separately in FIG. 3, the voltage control circuit 400 and the display driving circuit 500 can be set integrally, that is, integrated into a unified circuit. By introducing the electrically induced refractive index change layer, the display panel 10 can control an optical cavity length of the organic light-emitting diode device 100 and an optical path of the light in the organic light-emitting diode device 100, and further control and tune the emission wavelength of the organic light-emitting diode device 100 so as to enhance the color gamut and the image quality of the displayed images of the display panel 10, through controlling the voltage difference between a first electrode layer 111 and a second electrode layer 112.

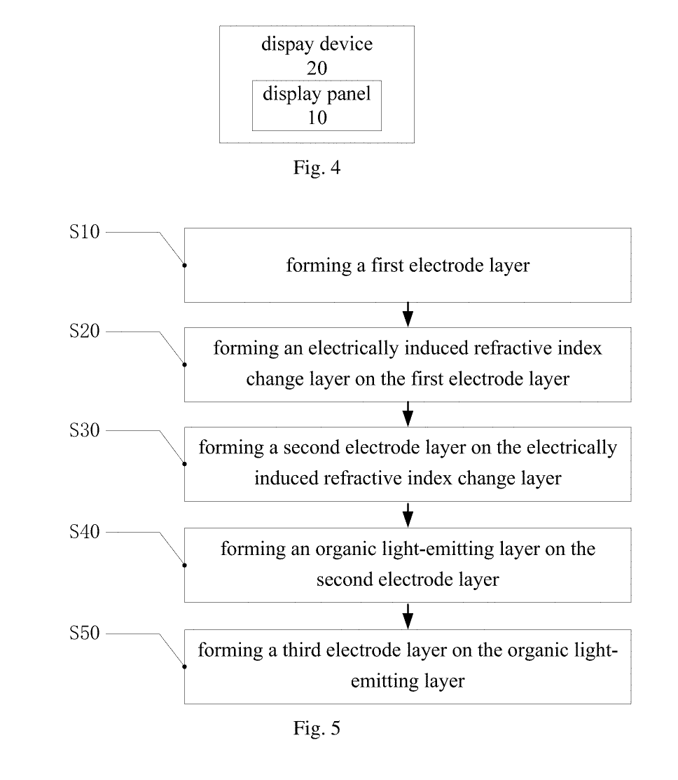

Another embodiment of the present disclosure provides a display device 20. As illustrated in FIG. 4, the display device 20 comprises the display panel 10, and the display panel 10 is the display panel of any one of embodiments of the present disclosure.

For example, the display device 20 can be any products or components that have a display function, such as a cellphone, a tablet computer, a television, a display device, a laptop, a digital photo frame, a navigator or the like.

It should be noted that those skilled in the art should understood the display device 20 has other necessary components for operation, for which the description is not repeated here and is not limitative to the present disclosure. By introducing the electrically induced refractive index change layer, the display device 20 can control and tune the emission wavelength of the organic light-emitting diode device, so as to increase the color gamut and the image quality of the displayed images of the display device.

For example, based on the same inventive concept, another embodiment of the present disclosure provides a manufacturing method of an organic light-emitting diode device. As illustrated in FIG. 5, the manufacturing method of an organic light-emitting diode device, taking the case illustrated in FIG. 1 for example, comprises the following steps:

Step S10: forming a first electrode layer;

Step S20: forming an electrically induced refractive index change layer on the first electrode layer;

Step S30: forming a second electrode layer on the electrically induced refractive index change layer;

Step S40: forming an organic light-emitting layer on the second electrode layer; and

Step S50: forming a third electrode layer on the organic light-emitting layer (e. g. forming the third electrode layer at a side of the second electrode layer away from the first electrode layer).

In another embodiment, the manufacturing method can comprise the following steps:

Step S110: forming a third electrode layer;

Step S120: forming an organic light-emitting layer on the third electrode layer;

Step S130: forming a second electrode layer on the organic light-emitting layer;

Step S140: forming an electrically induced refractive index change layer on the second electrode layer; and

Step S150: forming a first electrode layer on the electrically induced refractive index change layer.

For example, in order to provide protection, support and the like, the organic light-emitting diode device can be formed on a transparent substrate.

For example, in order to decrease the total reflection of the light emitted from the organic light-emitting layer while existing (at an interface formed by the light exiting surface and the outside environment medium) and increase output of the light, as for a top emission organic light-emitting diode device, a cover layer can be formed at a side of the third electrode layer, which side is away from the second electrode layer.

In the embodiments, the materials of the first electrode layer, the electrically induced refractive index change layer, the second electrode layer, the organic light-emitting layer, the third electrode layer, the substrate, the cover layer can be chosen according to the type of the organic light-emitting diode device (e.g., bottom emission type, top emission type or double-side emission type), which can be referred to the above and is not repeated here.

For example, taking the case illustrated in FIG. 2, compared to the case illustrated in FIG. 1, the manufacturing method of the organic light-emitting diode device provided by embodiments of the present disclosure can further comprise forming a hole transport layer, forming an electron transport layer, forming a hole injection layer and forming an electron injection layer.

For example, by introducing the electrically induced refractive index change layer, the organic light-emitting diode device can control the voltage difference between the first electrode layer and the second electrode layer to change the optical path of the light in the organic light-emitting diode device, and further control and tune the emission wavelength of the organic light-emitting diode device. Compared to tuning an optical path by changing a physical length, tuning the optical path by changing a refractive index can avoid mechanical movements during tuning the optical path and avoid the limitation to the tuning frequency caused by the mechanical movements, so as to increase the stability and the tuning frequency of the organic light-emitting diode device during tuning the optical path. Besides, the resonant cavity effect can also narrow full width at half maximum (FWHM) so as to enhance the color gamut and the image quality of the displayed images of the display device based on the organic light-emitting diode device.

Embodiments of the present disclosure provide an organic light-emitting diode device and a manufacturing method thereof, a display panel and a display device. By introducing an electrically induced refractive index change layer, an emission wavelength of the organic light-emitting diode device can be tuned, a wavelength of the light passing through the electrically induced refractive index change layer can be further tuned and the color deviation due to aging of the device can be reduced or eliminated.

Although detailed description has been given above to the present disclosure in connection with general description and embodiments, it shall be apparent to those skilled in the art that some modifications or improvements may be made on the basis of the embodiments of the present disclosure. Therefore, all the modifications or improvements made without departing from the spirit of the present disclosure shall all fall within the scope of protection of the present disclosure.

The application claims priority to the Chinese patent application No. 201610903223.8, filed on Oct. 17, 2016, the entire disclosure of which is incorporated herein by reference as part of the present application.

1. An organic light-emitting diode device, comprising:
a first electrode layer;
a second electrode layer, which is at least partially overlapped with the first electrode layer;
a third electrode layer, which is disposed at a side of the second electrode layer away from the first electrode layer and is at least partially overlapped with the second electrode layer;
an electrically induced refractive index change layer, which is disposes between the first electrode layer and the second electrode layer; and
an organic light-emitting layer, which is disposed between the second electrode layer and the third electrode layer;
wherein the electrically induced refractive index change layer is configured to allow a refractive index of the electrically induced refractive index change layer to be changed according to a voltage difference between the first electrode layer and the second electrode layer in operation; and
the organic light-emitting layer is configured to emit light in operation according to a voltage difference between the second electrode layer and the third electrode layer.

2. The organic light-emitting diode device according to claim 1, wherein a material for forming the electrically induced refractive index change layer comprises at least one of an electro-optical ceramic material, an organic electro-optical material, and an electro-optical crystalline material.

3. The organic light-emitting diode device according to claim 1, wherein a material for forming the electrically induced refractive index change layer comprises an organic fluorescence luminescent material or an organic phosphorescent luminescent material.

4. The organic light-emitting diode device according to claim 1, wherein the second electrode layer is a transparent conductive layer, and a material for forming the second electrode layer comprise any one or any combination of indium tin oxide, indium zinc oxide, zinc oxide, and aluminum zinc oxide.

5. The organic light-emitting diode device according to claim 1, wherein the first electrode layer is a metal layer.

6. The organic light-emitting diode device according to claim 5, wherein the third electrode layer is a transparent conductive layer and a material for forming the third electrode layer comprises any one or any combination of a transparent alloy material and a transparent conductive oxide material.

7. The organic light-emitting diode device according to claim 6, further comprising a cover layer, which is disposed on the third electrode layer and at a side of the third electrode layer away from the second electrode layer.

8. The organic light-emitting diode device according to claim 1, wherein the first electrode layer is a transparent conductive layer and a material for forming the first electrode layer comprises any one or any combination of a transparent conductive glass material, a transparent conductive oxide material and a transparent alloy material.

9. The organic light-emitting diode device according to claim 8, wherein a material for forming the third electrode layer comprises any one or any combination of a metal material, a metal alloy material, a transparent alloy material and a transparent conductive oxide material.

10. A display panel, comprising the organic light-emitting diode device of claim 1.

11. The display panel according to claim 10, comprising a plurality of pixels, wherein the organic light-emitting diode device is disposed at least one of the plurality of pixels.

12. The display panel according to claim 10, further comprising a voltage control circuit, wherein the voltage control circuit is configured to apply a first voltage to the first electrode layer and apply a second voltage to the second electrode layer.

13. The display panel according to claim 10, further comprising a display driving circuit, wherein the display driving circuit is configured to apply a third voltage to the third electrode layer.

14. A manufacturing method of the organic light-emitting diode device according to claim 1, comprising:
forming the first electrode layer;
forming the second electrode layer;
forming the third electrode layer at the side of the second electrode layer away from the first electrode layer;
forming the electrically induced refractive index change layer between the first electrode layer and the second electrode layer; and
forming the organic light-emitting layer between the second electrode layer and the third electrode layer.

15. The manufacturing method according to claim 14, further comprising:
forming a cover layer at a side of the third electrode layer away from the second electrode layer.

16. The organic light-emitting diode device according to claim 3, wherein the first electrode layer is a metal layer.

17. The organic light-emitting diode device according to claim 16, wherein the third electrode layer is a transparent conductive layer and a material for forming the third electrode layer comprises any one or any combination of a transparent alloy material and a transparent conductive oxide material.

18. The organic light-emitting diode device according to claim 17, further comprising a cover layer, which is disposed on the third electrode layer and at a side of the third electrode layer away from the second electrode layer.
